(19) United States
(12) Patent Application Publication
(10) Pub. No.: US 2016/0027932 A1
(43) Pub. Date: Jan. 28, 2016

(54) Solar Cells Having a Novel Bus Bar Structure

(71) Applicant: CHINA SUNERGY (NANJING) CO., LTD., Nanjing, Jiangsu (CN)

(72) Inventors: Jun Lu, Jiangsu (CN); Jilei Wang, Jiangsu (CN); Jiyuan Zhang, Jiangsu (CN); Yong-hong Zhang, Jiangsu (CN); Lei Liu, Jiangsu (CN); Aihua Wang, Jiangsu (CN); Jianhua Zhao, Jiangsu (CN)

(73) Assignee: China Sunergy (Nanjing) Co., Ltd., Jiangsu (CN)

(21) Appl. No.: 14/773,657

(22) PCT Filed: Mar. 8, 2013
(86) PCT No.: PCT/CN2013/072359

§ 371 Date: Sep. 8, 2015

(51) Int. Cl. H01L 31/02; H01L 31/05; H01L 31/0224

(52) U.S. Cl. CPC H01L 31/0201; H01L 31/022433; H01L 31/0504

(57) ABSTRACT

A solar cell (100) includes a photoelectric conversion layer (120) having a front surface (121) and a back surface (123), a back electrode (110) disposed on the back surface (123) of the photoelectric conversion layer (120), a plurality of electrically conductive fingers (130) disposed on the front surface (121) of the photoelectric conversion layer (120), and a plurality of primary bus bars (140) disposed on the front surface (121) of the photoelectric conversion layer (120). Each primary bus bar (140) is electrically connected to a plurality of electrically conductive fingers (130). The solar cell (100) can include from 4 to 12 primary bus bars (140) on the front surface (121) of the photoelectric conversion layer (120) and the primary bus bars (140) on the front surface (121) of the photoelectric conversion layer (120) have a total surface area of at most about 4 cm².

### TECHNICAL FIELD

This disclosure relates to solar cells having a novel bus bar structure, as well as related modules and methods.

### BACKGROUND

Solar cells (also known as photovoltaic cells) convert light into electrical energy. In general, a solar cell has a photoelectric conversion layer that, upon exposure to light, generates charge carriers, such as electrons. Electrodes in the solar cell conduct these electrons to an external device, thereby producing an electrical current.

One common solar cell technology collects the charge carriers by forming a plurality of electrically conductive fingers on the photoelectric conversion layer. These fingers conduct the collected charge carriers to a bus bar, which has a large surface for electrically connecting the fingers to an external device. In general, the electrically conductive fingers and the bus bar form an electrode on the photoelectric conversion layer.

### SUMMARY

This disclosure is based on the unexpected discovery that a silicon solar cell containing 4-12 primary bus bars can have higher photoelectric conversion efficiency (e.g., at least about 17%), higher mechanical strength, lower consumption of expensive conductive materials (e.g., silver), lower power loss, and better weak light performance compared to a conventional polycrystalline silicon solar cell (e.g., a solar cell having three bus bars).

In one aspect, this disclosure features a solar cell that includes a photoelectric conversion layer having a front surface and a back surface; a back electrode disposed on the back surface of the photoelectric conversion layer; a plurality of electrically conductive fingers disposed on the front surface of the photoelectric conversion layer; and a plurality of primary bus bars disposed on the front surface of the photoelectric conversion layer, each primary bus bar being electrically connected to a plurality of electrically conductive fingers. The solar cell includes from 4 to 12 primary bus bars on the front surface of the photoelectric conversion layer and the primary bus bars on the front surface of the photoelectric conversion layer have a total surface area of at most about 4 cm² (e.g., 3.5 cm²).

In another aspect, this disclosure features a solar cell that includes a photoelectric conversion layer having a front surface and a back surface; a back electrode disposed on the back surface of the photoelectric conversion layer; a plurality of electrically conductive fingers disposed on the front surface of the photoelectric conversion layer; and a plurality of non-uniform primary bus bars disposed on the front surface of the photoelectric conversion layer, each primary bus bar being electrically connected to a plurality of electrically conductive fingers. The solar cell includes from 4 to 12 primary bus bars on the front surface of the photoelectric conversion layer.

In still another aspect, this disclosure features a solar module that includes a plurality of the solar cells described above, in which the back electrode in each solar cell includes a plurality of primary bus bars. Each solar cell further includes a plurality of ribbons. Each ribbon covers and is electrically connected to a primary bus bar on the front surface of the photoelectric conversion layer or a primary bus bar in the back electrode. Each ribbon covering a primary bus bar on the front surface of the photoelectric conversion layer in a solar cell is electrically connected to a ribbon covering a primary bus bar in a back electrode in a neighboring solar cell.

Embodiments can include one or more of the following features.

In some embodiments, the solar cell can include from 5 to 10 (e.g., 5) primary bus bars on the front surface of the photoelectric conversion layer.

In some embodiments, each primary bus bar can include a plurality of nodes. The nodes can have a shape selected from the group consisting of circle, square, rectangle, diamond, star, ellipse, and a combination thereof. In some embodiments, each node can be electrically connected to at least one electrically conductive finger.

In some embodiments, at least one primary bus bar can include one or more secondary bus bars that electrically connect at least some of the nodes in the at least one primary bus bar. In some embodiments, the secondary bus bars can have an average width ranging from about 0.03 mm to about 2 mm.

In some embodiments, the back electrode can include a plurality of primary bus bars. In some embodiments, the back electrode can further include a metal layer between the photoelectric conversion layer and the primary bus bars in the back electrode, the metal layer being electrically connected to the primary bus bars in the back electrode.

In some embodiments, the back electrode can further include a plurality of electrically conductive fingers, the electrically conductive fingers being electrically connected to the primary bus bars in the back electrode.

In some embodiments, each primary bus bar in the back electrode can include a plurality of nodes and the nodes in two neighboring primary bus bars on the back electrodes can be arranged in an offset manner.

In some embodiments, the primary bus bars on the front surface of the photoelectric conversion layer or the primary bus bars in the back electrode have an average largest width ranging from about 0.01 mm to about 2 mm (e.g., 0.9 mm).

In some embodiments, the primary bus bars on the front surface of the photoelectric conversion layer or the primary bus bars in the back electrode can include silver.

In some embodiments, the solar cell can further include a plurality of ribbons, each ribbon covering and electrically connected to a primary bus bar on the front surface of the photoelectric conversion layer or a primary bus bar in the back electrode. In some embodiments, each ribbon can include copper coated with a solder.

In some embodiments, the solar cell is a silicon solar cell (e.g., a polycrystalline silicon solar cell). In some embodiments, the polycrystalline silicon solar cell can have a photoelectric conversion efficiency of at least about 17%.

In some embodiments, the primary bus bars are non-uniform (e.g., discontinuous).

Other features, objects, and advantages will be apparent from the description, drawings, and claims.

### DESCRIPTION OF DRAWINGS

FIG. 1 is a perspective view of an exemplary solar cell having five primary bus bars.

FIG. 2 is a graph demonstrating theoretical calculations of photoelectric conversion efficiencies of solar cells having different numbers of bus bars.

FIG. 3 is a top view of an exemplary solar cell having non-uniform primary bus bars containing nodes in different shapes.

FIG. 4 is a top view of an exemplary solar cell having non-uniform primary bus bars containing secondary bus bars.

FIG. 5 is a top view of an exemplary back electrode in a solar cell having a plurality of primary bus bars.

FIG. 6 is a graph comparing the performance of a solar cell having five bus bars to that of a solar cell having three bus bars

Like reference symbols in the various drawings indicate like elements.

### DETAILED DESCRIPTION

In general, this disclosure relates to solar cells having multiple bus bars (e.g., non-uniform bus bars).

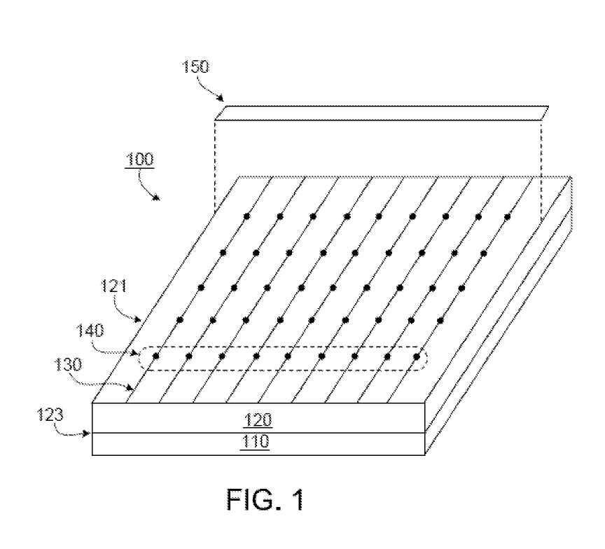

FIG. 1 shows a perspective view of an exemplary solar cell 100 (e.g., a polycrystalline silicon solar cell) that includes a back electrode 110, a photoelectric conversion layer 120, a plurality of electrically conductive fingers 130, a plurality of primary bus bars 140 (five primary bus bars shown in FIG. 1 as an example), and a plurality of ribbons 150 (only one ribbon shown in FIG. 1 as an example) covering and electrically connected to the primary bus bars 140, respectively. Photoelectric conversion layer 120 has a front surface 121 and a back surface 123. Back electrode 110 is disposed on back surface 123 of photoelectric conversion layer 120. Electrically conductive fingers 130 are disposed on front surface 121 of photoelectric conversion layer 120 and are substantially parallel to each other. Primary bus bars 140 are disposed on front surface 121 of photoelectric conversion layer 120 and are electrically connected to fingers 130. Each ribbon 150 covers and is electrically connected to a primary bus bar 140. Charge carriers (e.g., electrons) can be collected by fingers 130, conducted to bus bars 140, and then transferred to a neighboring solar cell or an external device through ribbons 150.

In general, photoelectric conversion layer 120 can be formed from any suitable material. In some embodiments, the materials that can be used to form layer 120 can include inorganic semiconductor materials or organic semiconductor materials. Exemplary inorganic semiconductor materials include silicon (e.g., monocrystalline silicon, polycrystalline silicon, or amorphous silicon), copper indium gallium selenide (CIGS), copper indium selenide (CIS), copper gallium selenide (CGS), copper gallium telluride (CGT), copper indium aluminum selenide (CIAS), cadmium selenide (CdSe), and cadmium telluride (CdTe). Exemplary organic semiconductor materials include conjugated polymers (e.g., polythiophenes, polyanilines, polycarbazoles, polyvinylcarbazoles, polyphenylenes, polyphenylvinylenes, polythienylenevinylenes, and copolymers thereof) and fullerenes (e.g., such substituted fullerenes such as [6,6]-phenyl C61-butyric acid methyl ester (PCBM)).

In some embodiments, photoelectric conversion layer 120 can have a thickness of at least about 100 μm (e.g., at least about 120 μm, at least about 140 μm, at least about 160 μm, at least about 180 μm, or at least about 200 μm) and/or at most about 300 μm (e.g., at most about 280 μm, at most about 260 μm, at most about 240 μm, at most about 220 μm, or at most about 200 μm).

In general, electrically conductive fingers 130 are a plurality of conductive lines disposed on front surface 121 of photoelectric conversion layer 120 and substantially parallel to each other. Fingers 130 are generally formed from an electrically conductive material (e.g., a metallic material such as silver).

In some embodiments, fingers 130 can have a relatively small width. For example, fingers 130 can have an average width of at most about 900 μm (e.g., at most about 800 μm, at most about 600 μm, at most about 400 μm, at most about 200 μm, at most about 100 μm, at most about 80 μm, or at most about 60 μm) and/or at least about 30 μm (e.g., at least about 40 μm, at least about 50 μm, at least about 60 μm, at least about 70 μm, at least about 80 μm, at least about 90 μm, or at least about 100 μm).

In general, solar cell 100 can include a plurality of primary bus bars 140. For example, solar cell 100 can include four, five, six, seven, eight, nine, ten, eleven, or twelve primary bus bars. In some embodiments, solar cell 100 can include a plurality of non-uniform primary bus bars. The term “non-uniform primary bus bar” mentioned herein refers to a bus bar having a non-uniform width (i.e., a portion of the bus bar having a width different from that of another portion of the bus bar). In some embodiments, a non-uniform primary bus bar can be a discontinuous primary bus bar. The term “discontinuous primary bus bar” mentioned herein refers to a primary bus bar having a discontinuous pattern (i.e., at least a portion of the bus bar is separated from at least another portion of the bus bar) when the primary bus bar is initially formed on a substrate (e.g., photoelectric conversion layer 120 shown in FIG. 1). Discontinuous primary bus bars mentioned herein are considered as discontinuous even though separated portions in a primary bus bar are eventually electrically connected by ribbons 150.

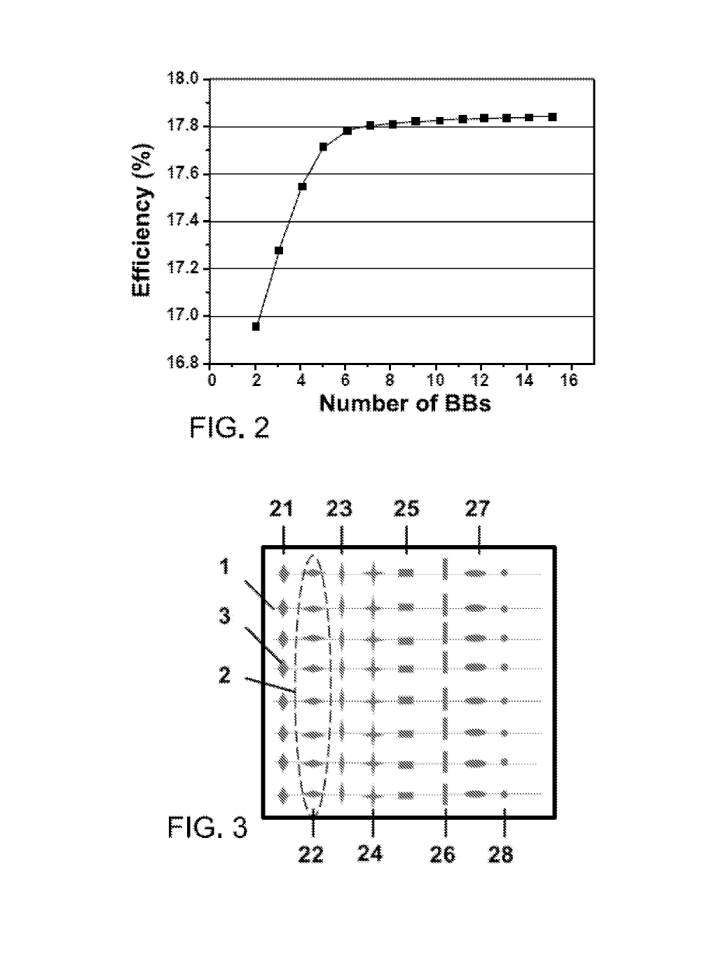

Without wishing to be bound by theory, it is believed that a solar cell having at least four bus bars can have a substantially improved photoelectric conversion efficiency compared to a conventional solar cell having three bus bars. On the other hand, without wishing to be bound by theory, it is believed that a solar cell having more than 12 bus bars would not have a photoelectric conversion efficiency substantially higher than those having 4-12 bus bars. FIG. 2 is a graph demonstrating theoretical calculations of photoelectric conversion efficiencies of solar cells having different numbers of bus bars. As shown in FIG. 2, solar cells having 4-6 bus bars have significantly higher photoelectric conversion efficiencies than a solar cell having three bus bars. Increasing the number of bus bars in a solar cell from 6 to 12 can slowly increase the photoelectric conversion efficiency of the solar cell. On the other hand, increasing the number of bus bars in a solar cell to 13 or more does not substantially increase the photoelectric conversion efficiency of the solar cell.

In general, each primary bus bar 140 includes a plurality of nodes and optionally a plurality of secondary bus bars (not shown in FIG. 1). Each bus bar 140 is electrically connected to the plurality of electrically conductive fingers 130 at the nodes such that charge carriers collected by fingers 130 can be conducted to bus bars 140 and subsequently conducted to an external device through ribbons 150. In some embodiments, each node in a bus bar 140 is electrically connected to only one finger 130. In other embodiments, each node in a bus bar 140 is electrically connected to two or more (e.g., three, four, or five) fingers 130. In some embodiments, the extending direction of primary bus bars 140 can be substantially perpendicular to the extending direction of electrically conductive fingers 130.

In some embodiments, the nodes in primary bus bars 140 can have suitable shapes. For example, the nodes in bus bars 140 can have a shape selected from the group consisting of circle, square, rectangle, diamond, star, ellipse, and a combination thereof. In some embodiments, all nodes in bus bars 140 in a solar cell can have the same shape. In some embodiments, nodes in different bus bars 140 in a solar cell have different shapes. FIG. 3 is a top view of an exemplary solar cell having electrically conductive fingers 1 connected to non-uniform primary bus bars 2 containing nodes 3 in different shapes. Specifically, primary bus bars 21-23 have nodes in a diamond shape (where the longer sides of the diamond nodes in bus bar 22 are horizontal and the longer sides of the diamond nodes in bus bars 21 and 23 are vertical), primary bus bar 24 has nodes in a star shape, primary bus bars 25 and 26 have nodes in a rectangular shape (where the longer sides of the rectangular nodes in bus bar 25 are horizontal and the longer sides of the rectangular nodes in bus bar 26 are vertical), primary bus bar 27 has nodes in an elliptical shape, and primary bus bar 28 has nodes in a circular shape. In some embodiments, solar cell 100 can have primary bus bars 140 in which the nodes within one bus bar can have different shapes.

As shown in FIG. 3, non-uniform primary bus bars 21-28 are discontinuous and have different widths at different portions. In general, the largest width of a non-uniform primary bus bar disclosed herein can be relatively small. In some embodiments, primary bus bars 21-28 shown in FIG. 3 can have an average largest width of at least about 0.01 mm (e.g., at least about 0.05 mm, at least about 0.1 mm, at least about 0.5 mm, at least about 0.9 mm, at least about 1.5 mm, at least about 2 mm, or at least about 5 mm) and/or at most about 80 mm (e.g., at most about 10 mm, at most about 5 mm, at most about 2 mm, at most about 1 mm, or at most about 0.5 mm). For example, primary bus bars 21-28 shown in FIG. 3 can have an average largest width of about 0.9 mm. Without wishing to be bound by theory, it has been unexpectedly discovered that, comparing to a conventional solar cell having three primary bus bars, using a relatively large number (e.g., 4-12) of primary bus bars with a relatively small width in a solar cell can significantly reduce consumption of expensive conductive materials (e.g., silver) while still maintaining or improving the photoelectric conversion efficiency (e.g., to at least about 17%) of the solar cell. In some embodiments, primary bus bars 140 shown in FIG. 1 can have an average largest width larger than that of electrically conductive fingers 130 to reduce electrical resistance.

In some embodiments, at least one (e.g., all) primary bus bar 140 can optionally include a plurality of secondary bus bars. FIG. 4 is a top view of an exemplary solar cell having non-uniform primary bus bars containing one or more secondary bus bars 20 that electrically connect at least some (e.g., all) of the nodes in a primary bus bar. In some embodiments, two nodes in a primary bus bar are electrically connected by one secondary bus bar 20. In some embodiments, two nodes in a primary bus bar are electrically connected by two or more (e.g., three or four) secondary bus bars. When two or more secondary bus bars are used to electrically connect two nodes in a primary bus bar, the two or more secondary bus bars can be substantially parallel to each other. Without wishing to be bound by theory, it is believed that using secondary bus bars to connect nodes in primary bus bars can significantly improve soldering strength between primary bus bars and ribbons, and significantly reduce power loss of a solar cell (e.g., caused by damage to the electrical connections between primary bus bars and ribbons or caused by soldering issues between primary bus bars and ribbons).

In some embodiments, secondary bus bars can have an average width smaller than the largest width of the nodes in primary bus bars 21-28. For example, secondary bus bars can have an average width of at least about 0.005 mm (e.g., at least about 0.1 mm, at least about 0.3 mm, at least about 0.5 mm, at least about 0.9 mm, at least about 1.5 mm, at least about 2 mm, or at least about 5 mm) and/or at most about 80 mm (e.g., at most about 10 mm, at most about 5 mm, at most about 2 mm, at most about 1 mm, or at most about 0.5 mm). In some embodiments, a non-uniform primary bus bar can include a plurality of nodes, all of which are electrically connected by secondary bus bars. In such embodiments, the secondary bus bars can have an average width smaller than the largest width of the nodes in the primary bus bar.

In general, primary bus bars 140 shown in FIG. 1 (including nodes and optional secondary bus bars) can have a relatively small total surface area compared to that in a conventional solar cell. In some embodiments, primary bus bars 140 in one solar cell can have a surface area of at most about 4 cm² (e.g., at most about 3.5 cm², at most about 3 cm², at most about 2.5 cm², or at most about 2 cm²) and/or at least about 0.1 cm² (e.g., at least about 0.5 cm², at least about 1 cm², at least about 1.5 cm², or at least about 2 cm²). Without wishing to be bound by theory, it has been unexpectedly found that, comparing to a conventional solar cell having three primary bus bars, using a relatively large number (e.g., 4-12) primary bus bars in a solar cell with a relatively small total surface area can significantly reduce consumption of expensive conductive materials (e.g., silver), thereby significantly reducing production costs, while still maintaining or improving the photoelectric conversion efficiency (e.g., to at least about 17%) of the solar cell.

In general, primary bus bars 140 shown in FIG. 1 (including nodes and optional secondary bus bars) are formed from an electrically conductive material. In some embodiments, the primary bus bars can be made from the same materials (e.g., a metallic material such as silver) as those used to form electrically conductive fingers described above.

Electrically conductive fingers 130 and primary bus bars 140 are generally formed on a substrate (e.g., photoelectric conversion layer 120) by using methods known in the art. In some embodiments, fingers 130 and bus bars 140 can be formed by using screen printing, electroplating, sputtering, or thermal evaporation. For example, fingers 130 and bus bars 140 can be formed by applying a silver paste to photoelectric conversion layer 120 by screen printing at predetermined locations and baking the silver paste at an elevated temperature (e.g., at least about 700° C.) to form fingers 130 and bus bars 130. In general, electrically conductive fingers 130 and primary bus bars 140 can constitute an electrode (e.g., a front electrode) of solar cell 100.

In general, solar cell 100 shown in FIG. 1 can further include a plurality of ribbons 150, which transfer charge carriers (e.g., electrons) generated in photoelectric conversion layer 120 to a neighboring solar cell or an external device. In some embodiments, each ribbon 150 covers and is electrically connected to a primary bus bar 140 on front surface 121 of photoelectric conversion layer 120. In some embodiments, ribbons 150 can have an average width that is substantially the same as or slightly larger than the average largest width of primary bus bars 140 to achieve an effective connection between ribbons 150 and bus bars 140.

Ribbons 150 are generally formed by materials known in the art. For example, ribbons 150 can be formed from an electrically conductive material (e.g., copper) that is coated with a solder (e.g., tin). In general, ribbons 150 can be a continuous sheet.

In some embodiments, ribbons 150 are electrically connected to primary bus bars 140 by soldering. For example, ribbons 150 can be electrically connected to primary bus bars 140 by (1) melting the solder in ribbons 150, (2) attaching ribbons 150 and bus bars 140 through the melted solder, and (3) cooling the melted solder to electrically connect ribbons 150 and bus bars 140.

In general, when a plurality of solar cells 100 are assembled to form a solar module, each ribbon 150 covering a primary bus bar 140 on front surface 121 of photoelectric conversion layer 120 in a solar cell can be electrically connected to a back electrode of a neighboring solar cell (e.g., to a ribbon covering a primary bus bar on the back surface of a photoelectric conversion layer in a neighboring solar cell).

Solar cell 100 generally has a back electrode 110 disposed on back surface 123 on photoelectric conversion layer 120. In some embodiments, back electrode 110 can be a homogeneous layer made from an electrically conductive material, such as a metal (e.g., aluminum, silver, or an alloy thereof). In some embodiments, back electrode 110 can be made from a plurality of electrically conductive fingers electrically connected to a plurality of primary bus bars. The primary bus bars in back electrode 110 can be either uniform or non-uniform. In some embodiments, when the primary bus bars in back electrode 110 are non-uniform, each of these bus bars can include a plurality of nodes and optionally one or more secondary bus bars, such as those described above with respect to primary bus bars 140. In such embodiments, the primary bus bars in back electrode 110 can be made from the same materials as those described above with respect to primary bus bars 140.

In some embodiments, back electrode 110 can further include a metal layer (e.g., an aluminum layer). The metal layer can be disposed between photoelectric conversion layer 120 and the plurality of primary bus bars in back electrode 110. Without wishing to be bound by theory, it is believed that the primary bus bars in back electrode 110 can facilitate soldering ribbons onto the metal layer in back electrode 110 (e.g., when the metal layer is not made of silver).

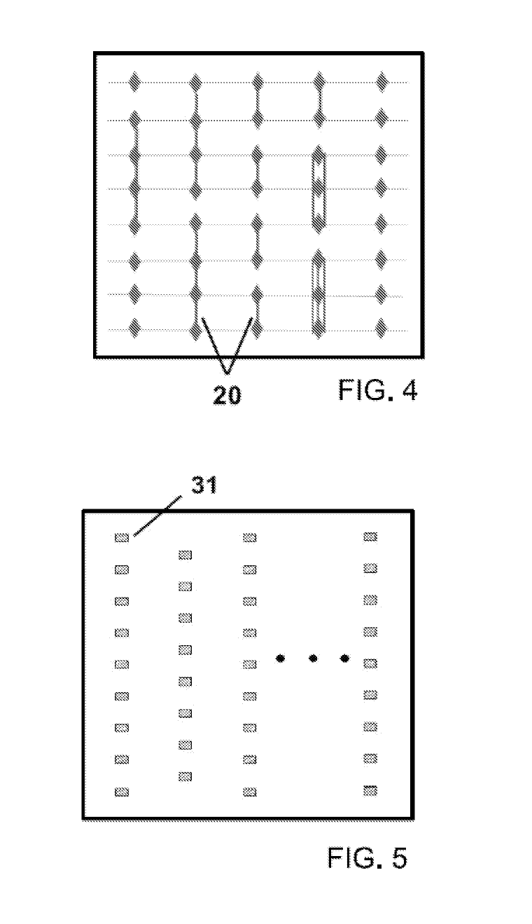

FIG. 5 is a top view of an exemplary back electrode in a solar cell having a plurality of non-uniform (i.e., discontinuous) primary bus bars 31. In some embodiments, the back electrode can have any suitable number (e.g., any number ranging from 1-30) of primary bus bars. In some embodiments, the back electrode can have the same number of primary bus bars as those in the front electrode (i.e., bus bars 140). In some embodiments, as shown in FIG. 5, each primary bus bar in the back electrode can include a plurality of nodes and the nodes in two neighboring primary bus bars in the back electrode are arranged in an offset manner. Without wishing to be bound by theory, it is believed that arranging two neighboring primary bus bars in the back electrode in an offset manner can reduce the distance for transferring charge carriers to the back electrode, thereby improving the photoelectric conversion efficiency of the solar cell.

In some embodiments, solar cell 100 can include a cathode as a back electrode and an anode as a front electrode. In certain embodiments, solar cell 100 can include an anode as a back electrode and a cathode as a front electrode.

In some embodiments, solar cell 100 can include an anti-reflective coating (not shown in FIG. 1) disposed on front surface 121 of photoelectric conversion layer 120 and covering electrically conductive fingers 130, primary bus bars 140, and ribbons 150. The anti-reflective coating can increase the amount of incident light that enters into photoelectric conversion layer 120.

In some embodiments, solar cell 100 can have a relatively large photoelectric conversion efficiency. For example, a polycrystalline silicon solar cell 100 can have a photoelectric conversion efficiency of at least about 17% (e.g., at least about 17.2%, at least about 17.4%, at least about 17.5%, at least about 18%, or at least about 19%).

In general, solar cell 100 can be made by methods known in the art. For example, solar cell 100 can be made as follows: A photoelectric conversion layer 120 (e.g., containing a monocrystalline or polycrystalline silicon layer) is first formed by doping a p-typed or n-typed silicon wafer (e.g., by injecting or diffusing phosphor into a p-typed silicon wafer or by injecting or diffusing boron into an n-typed silicon wafer). A back electrode 110 (e.g., an aluminum electrode) can be disposed on the back surface of photoelectric conversion layer 120. Electrically conductive fingers 130 and primary bus bars 140 can be disposed (either simultaneously or sequentially) on the front surface of photoelectric conversion layer 120, e.g., by screening printing. Ribbons 150 can then be disposed on primary bus bars 140, e.g., by soldering.

In some embodiments, multiple solar cells 100 can be electrically connected to form a solar module. In some embodiments, some (e.g., all) of the solar cells in a solar module can have one or more common substrates. In some embodiments, some (e.g., all) solar cells in a solar module are electrically connected in series. In some embodiments, some (e.g., all) of the solar cells in a solar module are electrically connected in parallel. In some embodiments, some solar cells in a solar module are electrically connected in series, while others solar cells in the solar module are electrically connected in parallel.

In some embodiments, a solar module made from solar cells 100 can have a relatively small power loss (e.g., caused by damage to the electrical connections between primary bus bars and ribbons or soldering issues between primary bus bars and ribbons). For example, a solar module made from solar cells 100 can have a power loss less than about 1% (e.g., less than about 0.8% or less than about 0.5%).

The contents of all publications cited herein (e.g., patents, patent application publications, and articles) are hereby incorporated by reference in their entirety.

The following examples are illustrative and not intended to be limiting.

### Example 1

The following two polycrystalline silicon solar cells were prepared: (1) a solar cell having three non-uniform primary bus bars in the front electrode and (2) a solar cell having five non-uniform primary bus bars in the front electrode. Specifically, a p-type polycrystalline silicon wafer was first cleaned and textured. A p-n junction was formed by diffusing or injecting phosphor into the wafer. An anti-reflective layer was subsequently coated on the wafer. Lastly, electrically conductive fingers, bus bars, and back electrode were formed on the wafer by screening printing. The wafer thus formed was sintered at about 800° C. to form a solar cell. The total surfaces area of the primary bus bars in the front electrode in solar cells (1) and (2) were about 4.6 cm² and 3.8 cm², respectively.

The performance of the two solar cells was tested under the illumination of a solar simulator, which has been calibrated to cast AM1.5 light, and analyzed by using a Berger SCLoad program.

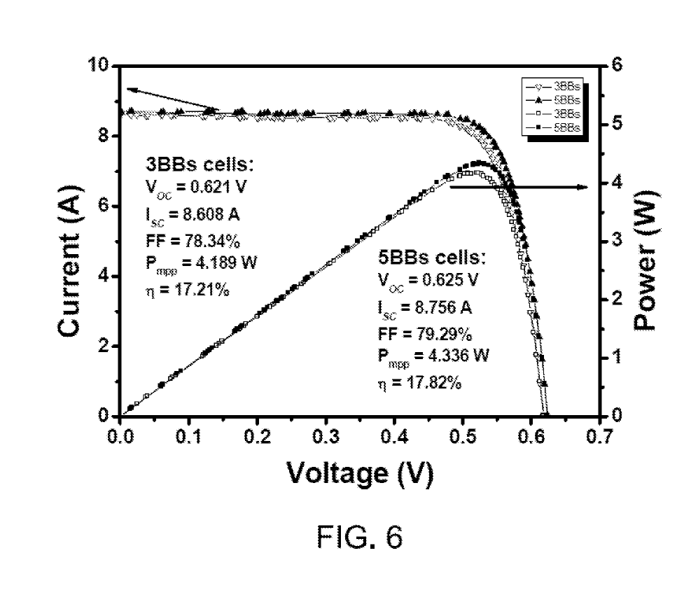

The results are shown in FIG. 6. As shown in FIG. 6, solar cell (1) exhibited a V_{oc} of 0.621 V, an I_{sc} of 8.608 A, a fill factor of 78.34%, and a photoelectric conversion efficiency of 17.21%. Unexpectedly, solar cell (2) exhibited a V_{oc} of 0.625 V, an I_{sc} of 8.756 A, a fill factor of 79.29%, and a photoelectric conversion efficiency of 17.82%. In other words, the solar cell having five bus bars with a total surface area of 3.8 cm² exhibited significantly better performance than the solar cell having three bus bars with a total surface area of 4.6 cm².

### Example 2

Two groups of solar modules were prepared as follows: Group (1) contained 10 solar modules, each having a total surface area of 156×156 mm². Each solar module was made by assembling 60 solar cells having 3 bus bars described in Example 1. Group (2) contained 10 solar modules, each having a total surface area of 156×156 mm². Each solar module was made by assembling 60 solar cells having 5 bus bars described in Example 1. Specifically, after the 60 solar cells were electrically connected through ribbons, they were inserted between two layers made from an ethylene-vinyl acetate (EVA) polymer. A piece of glass and a PET backsheet were put onto the front and back sides of the two EVA layers, respectively. The glass and PET backsheet were then laminated on the EVA layers in an automatic vacuum laminator. The article thus formed was then sealed with an aluminum frame to form a solar module.

The performance of the above two groups of solar modules was tested by using a Pasan module tester equipped with an AM1.5 light solar simulator in a dark room. The results are summarized in Table 1 below.

TABLE 1

| | | | | | | | Seal | Power |
|---|---|---|---|---|---|---|---|---|
| | | | V_{OC} | I_{SC} | | Iₘ | Eff. | loss |
| | No. | Pₘₐₓ | (V) | (A) | Vₘ (V) | (A) | (%) | (%) |
| 3BB | 1 | 246.39 | 38.171 | 8.598 | 30.593 | 8.054 | 98.11 | 1.89 |
| | 2 | 246.70 | 38.355 | 8.571 | 30.774 | 8.017 | 98.23 | 1.77 |
| | 3 | 247.27 | 38.325 | 8.612 | 30.776 | 8.034 | 98.46 | 1.54 |
| | 4 | 248.33 | 38.509 | 8.563 | 30.969 | 8.019 | 98.88 | 1.12 |
| | 5 | 247.84 | 38.494 | 8.604 | 30.558 | 8.110 | 98.68 | 1.32 |
| | 6 | 247.76 | 38.447 | 8.666 | 30.549 | 8.110 | 98.65 | 1.35 |
| | 7 | 246.97 | 38.377 | 8.683 | 30.422 | 8.118 | 98.34 | 1.66 |
| | 8 | 247.09 | 38.486 | 8.658 | 30.498 | 8.102 | 98.38 | 1.62 |
| | 9 | 247.85 | 38.508 | 8.627 | 30.532 | 8.118 | 98.69 | 1.31 |
| | 10 | 246.85 | 38.341 | 8.597 | 30.712 | 8.038 | 98.29 | 1.71 |
| 5BB | 1 | 259.46 | 38.094 | 8.957 | 30.889 | 8.400 | 99.83 | 0.17 |
| | 2 | 259.22 | 37.982 | 8.983 | 30.703 | 8.443 | 99.74 | 0.26 |
| | 3 | 258.70 | 38.032 | 8.949 | 30.843 | 8.388 | 99.54 | 0.46 |
| | 4 | 259.15 | 38.064 | 8.933 | 30.805 | 8.412 | 99.71 | 0.29 |
| | 5 | 258.79 | 38.090 | 8.944 | 30.876 | 8.382 | 99.57 | 0.43 |
| | 6 | 259.49 | 38.063 | 8.913 | 30.936 | 8.388 | 99.84 | 0.16 |
| | 7 | 259.06 | 38.055 | 8.946 | 30.741 | 8.427 | 99.67 | 0.33 |
| | 8 | 259.57 | 38.031 | 8.914 | 30.863 | 8.410 | 99.87 | 0.13 |
| | 9 | 259.37 | 38.007 | 8.900 | 30.870 | 8.402 | 99.79 | 0.21 |
| | 10 | 258.85 | 38.078 | 8.994 | 30.810 | 8.402 | 99.59 | 0.41 |

As shown in Table 1, it has been found unexpectedly that the solar modules in Group (2) had a maximum power (i.e., 258.70-259.57 W) higher than the maximum power (i.e., 246.39-248.33 W) of the solar modules in Group (1). In addition, unexpectedly, the solar modules in Group (2) exhibited a higher seal efficiency (i.e., greater than 99.5%) and a lower power loss (i.e., less than 0.5%) than those of the solar modules in Group (1). The seal efficiency is calculated by dividing the actual power of a solar module having 60 cells by the theoretical power of a solar module having 60 cells. The power loss is the difference between 100% and the seal efficiency.

Other embodiments are within the scope of the following claims.

What is claimed is:

1. A solar cell, comprising:
a photoelectric conversion layer having a front surface and a back surface;
a back electrode disposed on the back surface of the photoelectric conversion layer;
a plurality of electrically conductive fingers disposed on the front surface of the photoelectric conversion layer; and
a plurality of primary bus bars disposed on the front surface of the photoelectric conversion layer, each primary bus bar being electrically connected to a plurality of electrically conductive fingers;
wherein the solar cell comprises from 4 to 12 primary bus bars on the front surface of the photoelectric conversion layer, the primary bus bars on the front surface of the photoelectric conversion layer having a total surface area of at most about 4 cm².

2. The solar cell of claim 1, wherein the solar cell comprises from 5 to 10 primary bus bars on the front surface of the photoelectric conversion layer.

3. The solar cell of claim 1, wherein the solar cell comprises from 5 primary bus bars on the front surface of the photoelectric conversion layer.

4. The solar cell of claim 1, wherein each primary bus bar comprises a plurality of nodes.

5. The solar cell of claim 4, wherein the nodes have a shape selected from the group consisting of circle, square, rectangle, diamond, star, ellipse, and a combination thereof.

6. The solar cell of claim 4, wherein at least one primary bus bar comprises one or more secondary bus bars that electrically connect at least some of the nodes in the at least one primary bus bar.

7. The solar cell of claim 6, wherein the secondary bus bars have an average width ranging from about 0.03 mm to about 2 mm.

8. The solar cell of claim 4, wherein each node is electrically connected to at least one electrically conductive finger.

9. The solar cell of claim 1, wherein the back electrode comprises a plurality of primary bus bars.

10. The solar cell of claim 9, wherein the back electrode further comprises a metal layer between the photoelectric conversion layer and the primary bus bars in the back electrode, the metal layer being electrically connected to the primary bus bars in the back electrode.

11. The solar cell of claim 9, wherein the back electrode further comprises a plurality of electrically conductive fingers, the electrically conductive fingers being electrically connected to the primary bus bars in the back electrode.

12. The solar cell of claim 9, wherein each primary bus bar in the back electrode comprises a plurality of nodes and the nodes in two neighboring primary bus bars on the back electrodes are arranged in an offset manner.

13. The solar cell of claim 9, wherein the primary bus bars on the front surface of the photoelectric conversion layer or the primary bus bars in the back electrode have an average largest width ranging from about 0.01 mm to about 2 mm.

14. The solar cell of claim 13, wherein the primary bus bars on the front surface of the photoelectric conversion layer or the primary bus bars in the back electrode have an average largest width of about 0.9 mm.

15. The solar cell of claim 9, wherein the primary bus bars on the front surface of the photoelectric conversion layer or the primary bus bars in the back electrode comprise silver.

16. The solar cell of claim 9, wherein the solar cell further comprises a plurality of ribbons, each ribbon covering and electrically connected to a primary bus bar on the front surface of the photoelectric conversion layer or a primary bus bar in the back electrode.

17. The solar cell of claim 16, wherein each ribbon comprises copper coated with a solder.

18. The solar cell of claim 1, wherein the primary bus bars on the front surface of the photoelectric conversion layer have a total surface area of at most about 3.5 cm².

19. The solar cell of claim 1, wherein the solar cell is a silicon solar cell.

20. The solar cell of claim 19, wherein the solar cell is a polycrystalline silicon solar cell.

21. The solar cell of claim 20, wherein the polycrystalline silicon solar cell has a photoelectric conversion efficiency of at least about 17%.

22. The solar cell of claim 1, wherein the primary bus bars are non-uniform.

23. A solar cell, comprising:
a photoelectric conversion layer having a front surface and a back surface;
a back electrode disposed on the back surface of the photoelectric conversion layer;
a plurality of electrically conductive fingers disposed on the front surface of the photoelectric conversion layer; and
a plurality of non-uniform primary bus bars disposed on the front surface of the photoelectric conversion layer, each primary bus bar being electrically connected to a plurality of electrically conductive fingers;
wherein the solar cell comprises from 4 to 12 primary bus bars on the front surface of the photoelectric conversion layer.

24. The solar cell of claim 23, wherein the non-uniform primary bus bars are discontinuous.

25. A solar module, comprising:
a plurality of solar cells of any of claims 1-24, in which the back electrode in each solar cell comprises a plurality of primary bus bars;
wherein each solar cell further comprises a plurality of ribbons, each ribbon covers and is electrically connected to a primary bus bar on the front surface of the photoelectric conversion layer or a primary bus bar in the back electrode, and each ribbon covering a primary bus bar on the front surface of the photoelectric conversion layer in a solar cell is electrically connected to a ribbon covering a primary bus bar in a back electrode in a neighboring solar cell.
